(19) United States
(12) Patent Application Publication
(10) Pub. No.: US 2023/0170323 A1
(43) Pub. Date: Jun. 1, 2023

(54) SEMICONDUCTOR DEVICE, POWER CONVERTER, MOVING VEHICLE, AND SEMICONDUCTOR DEVICE MANUFACTURING METHOD

(71) Applicant: Mitsubishi Electric Corporation, Tokyo (JP)

(72) Inventor: Ryutaro DATE, Tokyo (JP)

(73) Assignee: Mitsubishi Electric Corporation, Tokyo (JP)

(21) Appl. No.: 17/996,774

(22) PCT Filed: Jul. 22, 2020
(86) PCT No.: PCT/JP2020/028516

§ 371 Date: Oct. 20, 2022

(51) Int. Cl. H01L 23/00; H01L 23/373; H01L 21/48

(52) U.S. Cl. CPC H01L 24/40; H01L 23/3735; H01L 24/48; H01L 24/84; H01L 21/4807; H02P 27/08

(57) ABSTRACT

It is an object to provide technology enabling suppression of scattering of metal powder during ultrasonic bonding to suppress discharge and abnormal operation of a semiconductor device. A semiconductor device includes: an insulating substrate including an insulating layer and a metal pattern disposed on the insulating layer; and an electrode bonded on the metal pattern. The electrode includes, in a portion inward of a peripheral portion of a bonded surface being a surface of the electrode bonded on the metal pattern, a receiving portion recessed upward and capable of receiving metal powder generated during bonding of the electrode and the metal pattern, and the peripheral portion of the bonded surface of the electrode is bonded on the metal pattern.

### TECHNICAL FIELD

The present disclosure relates to semiconductor devices, power converters, moving vehicles, and semiconductor device manufacturing methods.

### BACKGROUND ART

A lead frame has recently been used as an electrode having a high heat cycle resistance and suitable for high temperature operation as miniaturization and densification of a semiconductor device continue. As such, ultrasonic bonding is increasingly being used when the electrode is bonded on a metal pattern forming a side of the surface of an insulating substrate.

For example, Patent Document 1 proposes a method of forming a projection on a surface of an electrode to increase a bond strength during ultrasonic bonding.

### PRIOR ART DOCUMENTS

### Patent Document

Patent Document 1: Japanese Patent Application Laid-Open No. 2005-259880

### SUMMARY

### Problem to be Solved by the Invention

A conventional method, however, has a problem in that vibration during ultrasonic bonding scatters metal powder generated at a bonded surface of an electrode bonded to a metal pattern into a semiconductor device to cause discharge and abnormal operation of the semiconductor device.

It is thus an object of the present disclosure to provide technology enabling suppression of scattering of metal powder during ultrasonic bonding to suppress discharge and abnormal operation of a semiconductor device.

### Means to Solve the Problem

A semiconductor device according to the present disclosure includes: an insulating substrate including an insulating layer and a metal pattern disposed on the insulating layer, and an electrode bonded on the metal pattern, wherein the electrode includes a receiving portion recessed upward and capable of receiving metal powder generated during bonding of the electrode and the metal pattern in a portion inward of a peripheral portion of a bonded surface being a surface of the electrode bonded on the metal pattern, and the peripheral portion of the bonded surface of the electrode is bonded on the metal pattern.

### Effects of the Invention

According to the present disclosure, the metal powder generated during bonding of the electrode and the metal pattern is received in the receiving portion to suppress scattering of the metal powder. Discharge and abnormal operation of the semiconductor device caused by the metal powder can thereby be suppressed.

The objects, features, aspects and advantages of the present disclosure will become more apparent from the following detailed description and the accompanying drawings.

### BRIEF DESCRIPTION OF DRAWINGS

FIG. 1 is a schematic cross-sectional view of a semiconductor device according to Embodiment 1.

FIG. 2 is an illustration of ultrasonic bonding of an electrode and a metal pattern of the semiconductor device according to Embodiment 1.

FIG. 3 illustrates a bonded surface of the electrode of the semiconductor device according to Embodiment 1 viewed from below.

FIG. 4 illustrates a portion of the metal pattern of the semiconductor device according to Embodiment 1 opposing the bonded surface of the electrode viewed from above.

FIG. 5 is an illustration of ultrasonic bonding of an electrode and a metal pattern of a semiconductor device according to Embodiment 2.

FIG. 6 illustrates a bonded surface of the electrode of the semiconductor device according to Embodiment 2 viewed from below.

FIG. 7 is an illustration of ultrasonic bonding of an electrode and a metal pattern of a semiconductor device according to Embodiment 3.

FIG. 8 illustrates a bonded surface of the electrode of the semiconductor device according to Embodiment 3 viewed from below.

FIG. 9 is an illustration of ultrasonic bonding of un electrode and a metal pattern of a semiconductor device according to Embodiment 4.

FIG. 10 illustrates a portion of the metal pattern of the semiconductor device according to Embodiment 4 opposing a bonded surface of the electrode viewed from above.

FIG. 11 is an illustration of ultrasonic bonding of an electrode and a metal pattern of a semiconductor device according to Embodiment 5.

FIG. 12 illustrates a portion of the metal pattern of the semiconductor device according to Embodiment 5 opposing a bonded surface of the electrode viewed from above.

FIG. 13 is an illustration of ultrasonic bonding of an electrode and a metal pattern of a semiconductor device according to Embodiment 6.

FIG. 14 illustrates a portion of the metal pattern of the semiconductor device according to Embodiment 6 opposing a bonded surface of the electrode viewed from above.

FIG. 15 is a block diagram showing a configuration of a power conversion system including a power converter according to Embodiment 7.

FIG. 16 is a block diagram showing a configuration of a moving vehicle according to Embodiment 8.

### DESCRIPTION OF EMBODIMENTS

### Embodiment 1

Embodiment 1 will be described below with reference to the drawings. FIG. 1 is a schematic cross-sectional view of a semiconductor device 50 according to Embodiment 1.

As illustrated in FIG. 1, the semiconductor device 50 includes an insulating substrate 1, a semiconductor element 20, and an electrode 10.

The insulating substrate 1 includes an insulating layer 2, a metal pattern 3, and a lower surface pattern 4. The insulating layer 2 is made of ceramics or epoxy resin. The metal pattern 3 is disposed on an upper surface of the insulating layer 2, and the lower surface pattern 4 is disposed on a lower surface of the insulating layer 2. The metal pattern 3 is divided into two portions, for example.

The semiconductor element 20 is fixed to an upper surface of the insulating substrate 1, more specifically, to an upper surface of the metal pattern 3. The semiconductor element 20 is connected, via a wire 21, to a metal pattern 3 different from the metal pattern 3 to which the semiconductor element 20 is fixed. While only one semiconductor element 20 is illustrated in FIG. 1, a plurality of semiconductor elements 20 may be arranged.

The semiconductor element 20 is an insulated gate bipolar transistor (IGBT) chip, a diode (Di) chip, or a metal oxide semiconductor field effect transistor (MOSFET) chip. In a case where the plurality of semiconductor elements 20 are arranged herein, some of the IGBT chip, the Di chip, and the MOSFET chip may be combined.

The electrode 10 is a lead frame, and is bonded to the upper surface of the metal pattern 3 by ultrasonic bonding. The semiconductor device 50 further includes a case, a base plate, a lid, a sealing material, and the like, which are not illustrated, and the insulating substrate 1, the semiconductor element 20, and the electrode 10 are protected by the case and the sealing material.

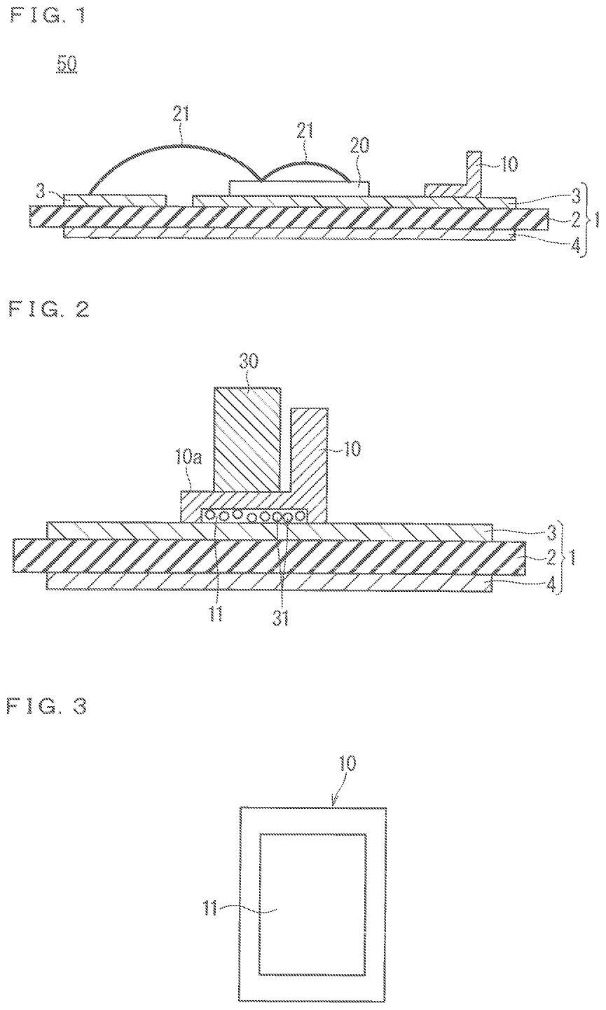

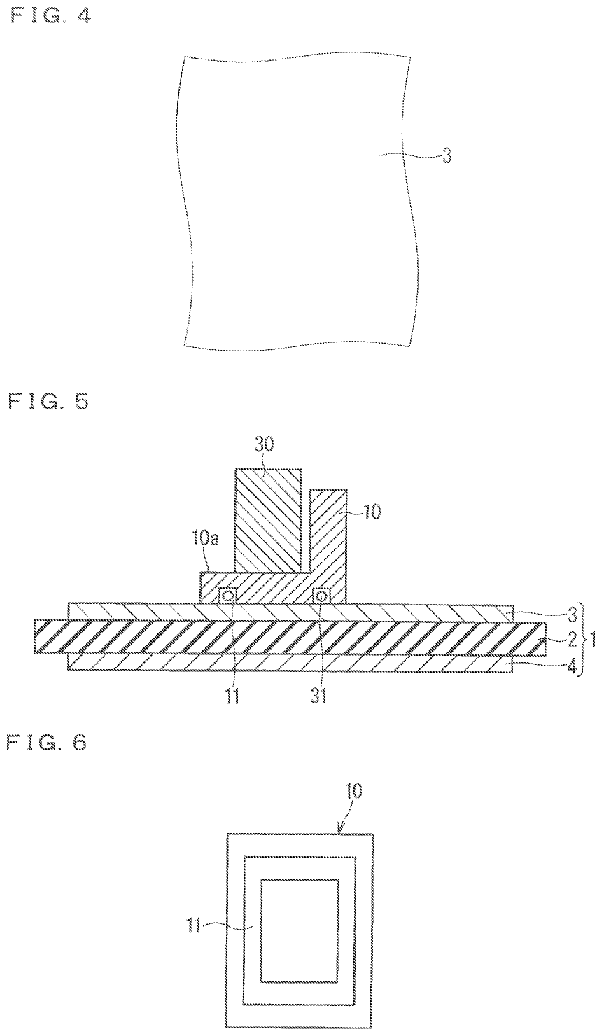

Bonding of the electrode 10 and the metal pattern 3 will be described next with reference to FIGS. 2 to 4. FIG. 2 is an illustration of ultrasonic bonding of the electrode 10 and the metal pattern 3. FIG. 3 illustrates a bonded surface of the electrode 10 viewed from below. FIG. 4 illustrates a portion of the metal pattern 3 opposing the bonded surface of the electrode 10 viewed from above.

As illustrated in FIGS. 2 and 3, the electrode 10 includes a receiving portion 11 capable of receiving metal powder 31 generated during bonding of the electrode 10 and the metal pattern 3. The electrode 10 includes the receiving portion 11 in a portion inward of a peripheral portion of the bonded surface being a surface of the electrode 10 bonded on the metal pattern 3. More specifically, the receiving portion 11 is a recess formed in a central portion of the bonded surface of the electrode 10 and recessed upward.

While the receiving portion 11 is formed to be rectangular when viewed from below, the shape of the receiving portion 11 is not limited to this shape, and the receiving portion 11 may be formed to be circular when viewed from below. On the other hand, the peripheral portion of the bonded surface of the electrode 10 is formed to be planar. That is to say, the peripheral portion of the bonded surface of the electrode 10 protrudes downward relative to the receiving portion 11.

As illustrated in FIGS. 2 and 4, the portion of the metal pattern 3 opposing the bonded surface of the electrode 10 is formed to be planar. The portion of the metal pattern 3 opposing the bonded surface of the electrode 10 is thus in contact with the peripheral portion of the bonded surface of the electrode 10.

A method of bonding the electrode 10 and the metal pattern 3 of a semiconductor device manufacturing method will be described next.

First, the insulating substrate 1 and the electrode 10 are prepared. Next, as illustrated in FIG. 2, the peripheral portion of the bonded surface of the electrode 10 is brought into contact with the metal pattern 3, and is ultrasonically bonded on the metal pattern 3 while a load is applied to an upper surface of a bonded portion 10a of the electrode 10 using an ultrasonic bonding tool 30. The metal powder 31 is generated due to rubbing of the electrode 10 and the metal pattern 3 against each other during ultrasonic bonding, but the metal powder 31 is received in the receiving portion 11 formed in the bonded surface of the electrode 10 to suppress scattering of the metal powder. The bonded portion 10a of the electrode 10 is a portion at one end side of the electrode 10 bonded on the metal pattern 3, and a lower surface of the bonded portion 10a is the bonded surface of the electrode 10.

As described above, the semiconductor device 50 according to Embodiment 1 includes: the insulating substrate 1 including the insulating layer 2 and the metal pattern 3 disposed on the insulating layer 2; and the electrode 10 bonded on the metal pattern 3, the electrode 10 includes, in the portion inward of the peripheral portion of the bonded surface being the surface of the electrode 10 bonded on the metal pattern 3, the receiving portion 11 recessed upward and capable of receiving the metal powder 31 generated during bonding of the electrode 10 and the metal pattern 3, and the peripheral portion of the bonded surface of the electrode 10 is bonded on the metal pattern 3.

The metal powder 31 generated during bonding of the electrode 10 and the metal pattern 3 is received in the receiving portion 11 to suppress scattering of the metal powder 31. Discharge and abnormal operation of the semiconductor device 50 caused by the metal powder 31 can thereby be suppressed. Reliability of the semiconductor device 50 can thereby be improved.

Suppression of scattering of the metal powder 31 allows for saving of man-hours required for removal of the scattered metal powder 31 and visual inspection of the semiconductor device.

The receiving portion 11 is the recess formed in the central portion of the bonded surface of the electrode 10, so that a ratio of the receiving portion 11 to the bonded surface of the electrode 10 increases to improve capacity for receiving the metal powder 31. An effect of suppressing scattering of the metal powder 31 is thereby improved.

The semiconductor device 50 further includes the semiconductor element 20 bonded on the metal pattern 3, and the semiconductor element 20 includes a wide bandgap semiconductor, allowing for energy conservation of the semiconductor device 50.

### Embodiment 2

A semiconductor device according to Embodiment 2 will be described next. FIG. 5 is an illustration of ultrasonic bonding of the electrode 10 and the metal pattern 3 of the semiconductor device 50 according to Embodiment 2. FIG. 6 illustrates the bonded surface of the electrode 10 viewed from below. In Embodiment 2, the same components as those described in Embodiment 1 bear the same reference signs as those of the components described in Embodiment 1, and description thereof will be omitted.

As illustrated in FIGS. 5 and 6, the receiving portion 11 is a groove formed along the peripheral portion of the bonded surface of the electrode 10 in Embodiment 2.

While the receiving portion 11 is formed in the shape of a rectangular frame when viewed from below in FIG. 6, the shape of the receiving portion 11 is not limited to this shape, and the receiving portion 11 may be formed to be annular when viewed from below. On the other hand, the peripheral portion and a central portion of the bonded surface of the electrode 10 are formed to be planar. That is to say, the peripheral portion and the central portion of the bonded surface of the electrode 10 protrude downward relative to the receiving portion 11.

As in a case of Embodiment 1, the portion of the metal pattern 3 opposing the bonded surface of the electrode 10 is formed to be planar. The portion of the metal pattern 3 opposing the bonded surface of the electrode 10 is thus in contact with the peripheral portion and the central portion of the bonded surface of the electrode 10.

As described above, in the semiconductor device 50 according to Embodiment 2, the receiving portion 11 is the groove formed along the peripheral portion of the bonded surface of the electrode 10, so that a bond area of the electrode 10 and the metal pattern 3 can be increased compared with a case of Embodiment 1. A bond strength of the electrode 10 and the metal pattern 3 can thereby be improved.

### Embodiment 3

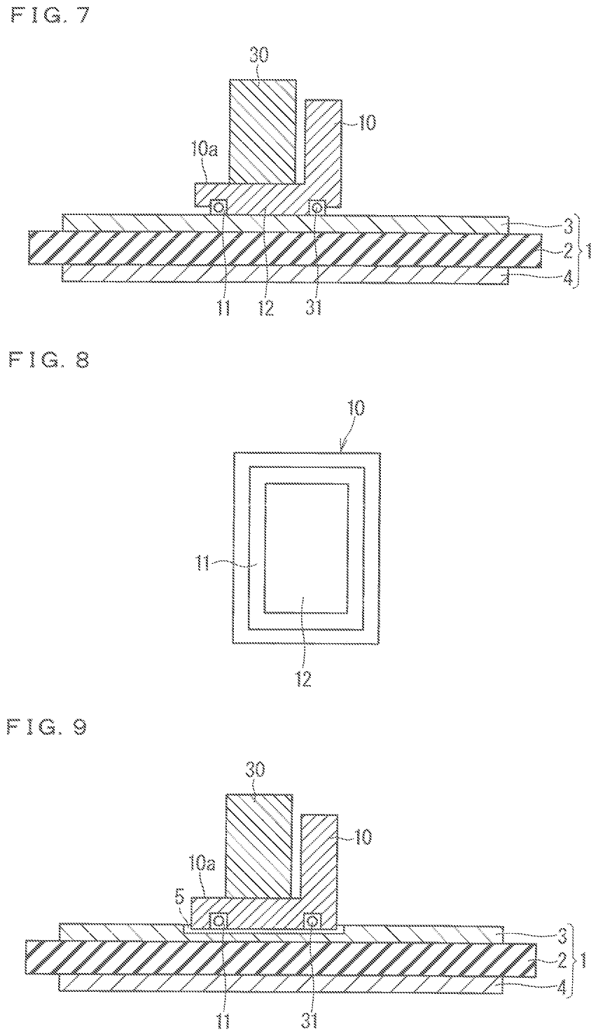

A semiconductor device manufacturing method according to Embodiment 3 will be described next. FIG. 7 is an illustration of ultrasonic bonding of the electrode 10 and the metal pattern 3 of the semiconductor device 50 according to Embodiment 3. FIG. 8 illustrates the bonded surface of the electrode 10 viewed from below. In Embodiment 3, the same components as those described in Embodiments 1 and 2 bear the same reference signs as those of the components described in Embodiments 1 and 2, and description thereof will be omitted.

As illustrated in FIGS. 7 and 8, the receiving portion 11 is a groove formed along the peripheral portion of the bonded surface of the electrode 10 in Embodiment 3. In a state before bonding, the electrode 10 includes, in a portion inward of the receiving portion 11, that is, in a central portion of the bonded surface, a protrusion 12 protruding downward. In this case, there is a gap between the peripheral portion of the bonded surface of the electrode 10 and the metal pattern 3.

While the receiving portion 11 is formed in the shape of a rectangular frame when viewed from below and the protrusion 12 is formed to be rectangular when viewed from below in FIG. 8, the receiving portion 11 may be formed to be annular when viewed from below and the protrusion 12 may be formed to be circular when viewed from below.

The method of bonding the electrode 10 and the metal pattern 3 of the semiconductor device manufacturing method will be described next. The protrusion 12 of the bonded surface of the electrode 10 is brought into contact with the metal pattern 3, and is ultrasonically bonded on the metal pattern 3 while a load is applied to the upper surface of the bonded portion 10a of the electrode 10 using the ultrasonic bonding tool 30. The protrusion 12 is compressed by the load applied during ultrasonic bonding, so that the gap between the peripheral portion of the bonded surface of the electrode 10 and the metal pattern 3 is closed, and the peripheral portion of the bonded surface of the electrode 10 is bonded on the metal pattern 3. There is no gap between the peripheral portion of the bonded surface of the electrode 10 and the metal pattern 3, so that the metal powder 31 generated in the protrusion 12 can be received in the receiving portion 11.

As described above, in the semiconductor device manufacturing method according to Embodiment 3, the receiving portion 11 is the groove formed along the peripheral portion of the bonded surface of the electrode 10, and the electrode 10 includes, in the portion inward of the receiving portion 11, the protrusion 12 protruding downward.

The metal powder 31 generated in the central portion of the bonded surface of the electrode 10, that is, at the protrusion 12 of the electrode 10 can thus be received in the receiving portion 11, so that the effect of suppressing scattering of the metal powder 31 is improved.

### Embodiment 4

The semiconductor device 50 according to Embodiment 4 will be described next. FIG. 9 is an illustration of ultrasonic bonding of the electrode 10 and the metal pattern 3 of the semiconductor device 50 according to Embodiment 4. FIG. 10 illustrates the portion of the metal pattern 3 opposing the bonded surface of the electrode 10 viewed from above. In Embodiment 4, the same components as those described in Embodiments 1 to 3 bear the same reference signs as those of the components described in Embodiments 1 to 3, and description thereof will be omitted.

As illustrated in FIGS. 9 and 10, the metal pattern 3 includes, in the portion opposing the bonded surface of the electrode 10, a depression 5 recessed downward in Embodiment 4. Specifically, the metal pattern 3 includes the depression 5 in the portion opposing the bonded surface of the electrode 10 and in a peripheral region thereof. An outline of the depression 5 in plan view is thus greater than an outline of the bonded portion 10a of the electrode 10 in bottom view.

As described above, in the semiconductor device 50 according to Embodiment 4, the metal pattern 3 includes, in the portion of opposing the bonded surface of the electrode 10, the depression 5 recessed downward, so that the electrode 10 can easily be positioned relative to the metal pattern 3. The yield of the semiconductor device 50 in an ultrasonic bonding step can thereby be improved.

### Embodiment 5

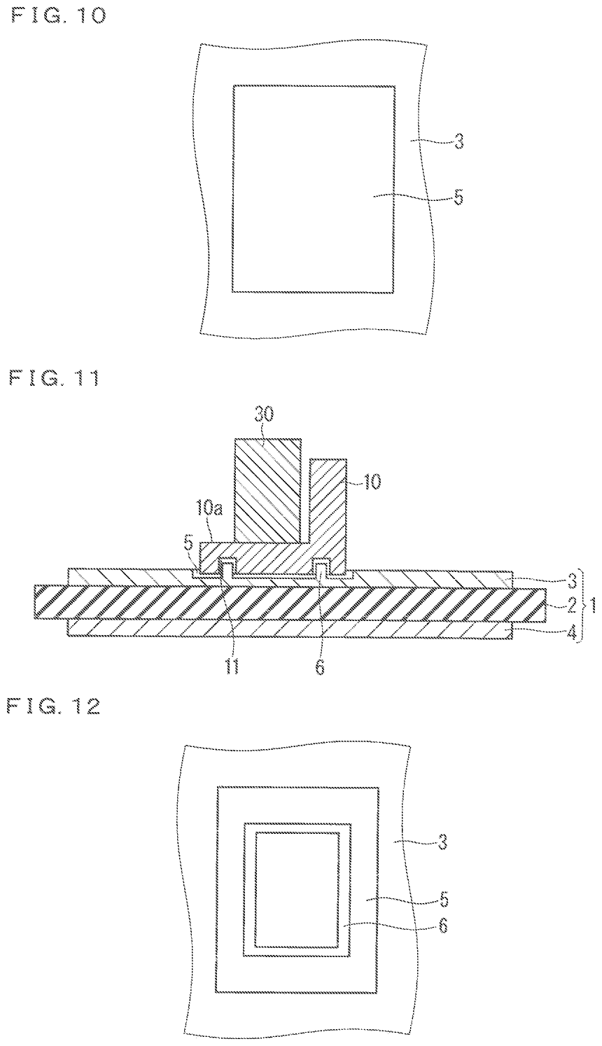

The semiconductor device 50 according to Embodiment 5 will be described next. FIG. 11 is an illustration of ultrasonic bonding of the electrode 10 and the metal pattern 3 of the semiconductor device 50 according to Embodiment 5. FIG. 12 illustrates the portion of the metal pattern 3 opposing the bonded surface of the electrode 10 viewed from above. In Embodiment 5, the same components as those described in Embodiments 1 to 4 bear the same reference signs as those of the components described in Embodiments 1 to 4, and description thereof will be omitted.

As illustrated in FIGS. 11 and 12, the metal pattern 3 includes the depression 5 as in a case of Embodiment 4. Furthermore, a projection 6 protruding upward and received in the receiving portion 11 of the electrode 10 is formed in the depression 5.

The projection 6 is formed to conform to the shape of the receiving portion 11. For example, when the receiving portion 11 is formed in the shape of a rectangular frame when viewed from below, the projection 6 is in the shape of a rectangular frame when viewed from above, and, when the receiving portion 11 is formed to be annular when viewed from below, the projection 6 is annular when viewed from above.

In a state of the projection 6 being received in the receiving portion 11, there is a gap between the receiving portion 11 and the projection 6, and the metal powder 31 is received in the gap.

As described above, in the semiconductor device 50 according to Embodiment 5, the metal pattern 3 includes, in the depression 5 thereof, the projection 6 protruding upward and received in the receiving portion 11 of the electrode 10. The metal powder 31 generated immediately below the ultrasonic bonding tool 30, that is, the metal powder 31 generated by friction between the receiving portion 11 and the projection 6 can be received in the gap between the receiving portion 11 and the projection 6, so that the effect of suppressing scattering of the metal powder 31 can further be increased.

The electrode 10 can more easily be positioned relative to the metal pattern 3 compared with a case of Embodiment 4. The yield of the semiconductor device 50 in the ultrasonic bonding step can thereby further be improved.

### Embodiment 6

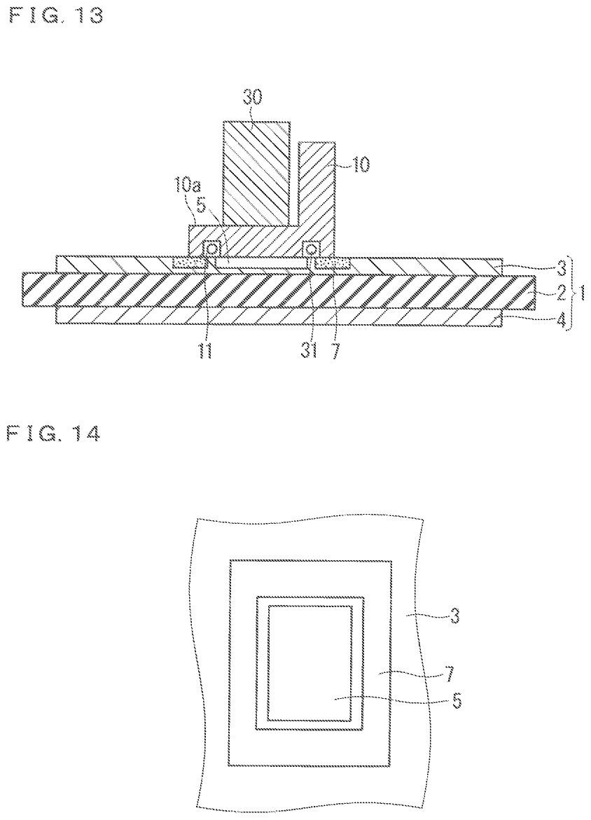

The semiconductor device 50 according to Embodiment 6 will be described next. FIG. 13 is an illustration of ultrasonic bonding of the electrode 10 and the metal pattern 3 of the semiconductor device 50 according to Embodiment 6. FIG. 14 illustrates the portion of the metal pattern 3 opposing the bonded surface of the electrode 10 viewed from above. In Embodiment 6, the same components as those described in Embodiments 1 to 5 bear the same reference signs as those of the components described in Embodiments 1 to 5, and description thereof will be omitted.

As illustrated in FIGS. 13 and 14, the metal pattern 3 includes, in a portion opposing the peripheral portion of the bonded surface of the electrode 10, a capture portion 7 capable of capturing the metal powder 31 in Embodiment 6. Specifically, the metal pattern 3 includes the capture portion 7 in the portion opposing the peripheral portion of the bonded surface of the electrode 10 and in a peripheral region thereof. The capture portion 7 is formed to conform to the shape of the peripheral portion of the bonded surface of the electrode 10, and is formed in the shape of a rectangular frame when viewed from above.

Furthermore, the capture portion 7 is made of a different material from the metal pattern 3. The different material from the metal pattern 3 is an adhesive, solder, and the like. The capture portion 7 is in any of a paste state before being solidified, a solidifying state, and a solidified state, and is capable of capturing the metal powder 31.

The depression 5 is formed in a portion inward of the capture portion 7, that is, in a central portion of the bonded surface of the electrode 10.

As described above, in the semiconductor device 50 according to Embodiment 6, the metal pattern 3 includes, in the portion opposing the peripheral portion of the bonded surface of the electrode 10, the capture portion 7 made of the different material from the metal pattern 3 and capable of capturing the metal powder 31.

The metal powder 31 generated by friction between the peripheral portion of the bonded surface of the electrode 10 and the metal pattern 3 can thus be captured by the capture portion 7. The effect of suppressing scattering of the metal powder 31 can thus further be increased.

### Embodiment 7

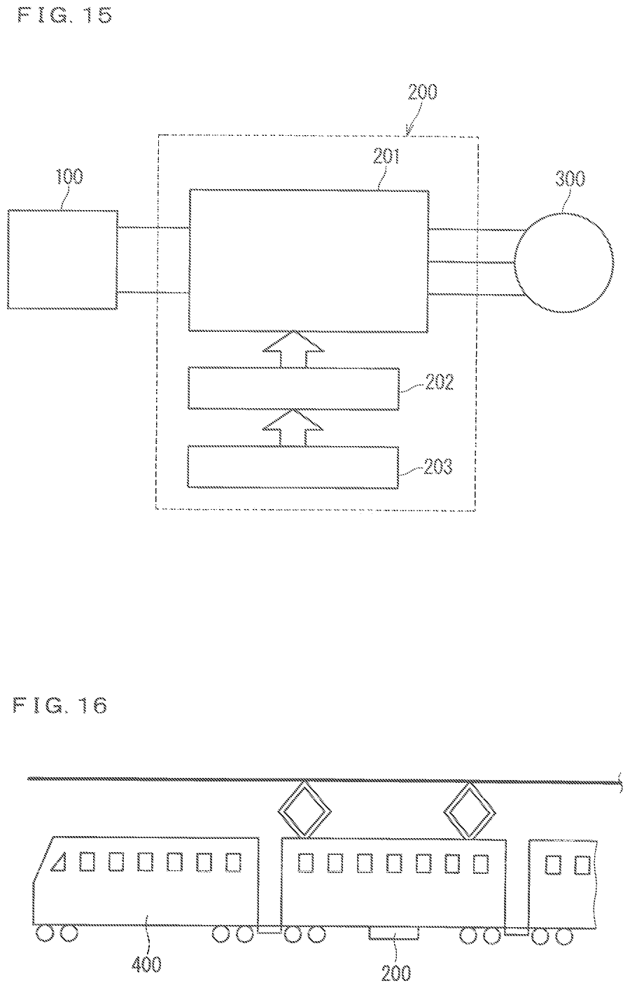

A power converter according to Embodiment 7 will be described next. FIG. 15 is a block diagram showing a configuration of a power conversion system including a power converter 200 according to Embodiment 7. In Embodiment 7, the same components as those described in Embodiments 1 to 6 bear the same reference signs as those of the components described in Embodiments 1 to 6, and description thereof will be omitted.

The power conversion system shown in FIG. 15 includes a power supply 100, the power converter 200, and a load 300. The power supply 100 is a DC power supply, and supplies DC power to the power converter 200. The power supply 100 can be configured by various power supplies, and, for example, may be configured by a DC system, a solar cell, or a storage battery, or may be configured by a rectifier circuit or an AC/DC converter connected to an AC system. The power supply 100 may be configured by a DC/IDC converter to convert DC power output from the DC system into predetermined power.

The power converter 200 is a three-phase inverter connected between the power supply 100 and the load 300, and converts the DC power supplied from the power supply 100 into AC power, and supplies the AC power to the load 300. As shown in FIG. 15, the power converter 200 includes a main conversion circuit 201 to convert the DC power into the AC power for output, a drive circuit 202 to output a drive signal to drive each of switching elements of the main conversion circuit 201, and a control circuit 203 to output, to the drive circuit 202, a control signal to control the drive circuit 202.

The load 300 is a three-phase motor driven by the AC power supplied from the power converter 200. The load 300 is not limited to that for a particular application, and is used as a motor mounted on various types of electrical equipment, for example, a motor for hybrid vehicles, electric vehicles, railroad vehicles, elevators, or air-conditioning equipment.

The power converter 200 will be described in detail below. The main conversion circuit 201 includes the switching elements and freewheeling diodes (not illustrated), and converts the DC power supplied from the power supply 100 into the AC power, and supplies the AC power to the load 300 through switching of the switching elements. The main conversion circuit 201 can have various specific circuit configurations, and the main conversion circuit 201 according to Embodiment 7 is a two-level three-phase full-bridge circuit, and can include six switching elements and six freewheeling diodes connected in anti-parallel with the respective switching elements. The semiconductor device 50 according to any one of Embodiments 1 to 6 described above is applied to at least one of the switching elements and the freewheeling diodes of the main conversion circuit 201. Every two switching elements out of the six switching elements are connected in series with each other to constitute pairs of upper and lower arms, and the pairs of upper and lower arms constitute respective phases (a U phase, a V phase, and a W phase) of the full-bridge circuit. Output terminals of the respective pairs of upper and lower arms, that is, three output terminals of the main conversion circuit 201 are connected to the load 300.

The drive circuit 202 generates the drive signal to drive each of the switching elements of the main conversion circuit 201, and supplies the drive signal to a control electrode of each of the switching elements of the main conversion circuit 201. Specifically, the drive circuit 202 outputs, to the control electrode of each of the switching elements, a drive signal to switch the switching element to an on state and a drive signal to switch the switching element to an off state in accordance with the control signal from the control circuit 203, which will be described below. The drive signal is a voltage signal (an on signal) equal to or greater than a threshold voltage of the switching element when the switching element is maintained in the on state, and is a voltage signal (an off signal) equal to or smaller than the threshold voltage of the switching element when the switching element is maintained in the off state.

The control circuit 203 controls the switching elements of the main conversion circuit 201 so that desired power is supplied to the load 300. Specifically, the control circuit 203 calculates time (on time) during which each of the switching elements of the main conversion circuit 201 is to be in the on state based on power to be supplied to the load 300. For example, the control circuit 203 can control the main conversion circuit 201 through pulse width modulation (PWM) control to modulate the on time of each of the switching elements in accordance with a voltage to be output. The control circuit 203 outputs a control command (the control signal) to the drive circuit 202 so that the on signal is output to a switching element to be in the on state, and the off signal is output to a switching element to be in the off state at each time point. The drive circuit 202 outputs, as the drive signal, the on signal or the off signal to the control electrode of each of the switching elements in accordance with the control signal.

In the power converter 200 according to Embodiment 7 as described above, the semiconductor device 50 according to any one of Embodiments 1 to 6 is applied to at least one of the switching elements and the freewheeling diodes of the main conversion circuit 201, so that reliability can be improved.

While an example in which the semiconductor device 50 according to any one of Embodiments 1 to 6 is applied to the two-level three-phase inverter has been described in Embodiment 7 described above, Embodiment 7 is not limited to this example, and is applicable to various power converters. While the semiconductor device 50 according to any one of Embodiments 1 to 6 is a two-level power converter in Embodiment 7, the power converter may be a three-level or multi-level power converter, and the above-mentioned semiconductor device 50 may be applied to a single-phase inverter when power is supplied to a single-phase load. The above-mentioned semiconductor device 50 is applicable to a DC/DC converter or an AC/DC converter when power is supplied to a DC load and the like.

The power converter 200 according to Embodiment 7 is not limited to that in the above-mentioned case where the load is the motor, and can be used as a power supply device of an electrical discharge machine, a laser machine, an induction cooker, or a noncontact power supply system, for example, and can further be used as a power conditioner of a photovoltaic system, a storage system, and the like.

### Embodiment 8

A moving vehicle 400 according to Embodiment 8 will be described next. FIG. 16 is a block diagram showing a configuration of the moving vehicle 400 according to Embodiment 8. In Embodiment 8, the same components as those described in Embodiments 1 to 7 bear the same reference signs as those of the components described in Embodiments 1 to 7, and description thereof will be omitted.

The moving vehicle 400 illustrated in FIG. 16 includes the power converter 200 according to Embodiment 7 mounted thereon, and the moving vehicle 400 is movable using an output from the power converter 200. According to such a configuration, the moving vehicle 400 can be made lighter due to miniaturization and weight saving of the converter. As a result, higher efficiency and higher performance of the moving vehicle 400 can be expected. While description is made on the assumption that the moving vehicle 400 is a railroad vehicle herein, the moving vehicle 400 is not limited to the railroad vehicle, and may be a hybrid vehicle, an electric vehicle, an elevator, and the like.

While the present disclosure has been described in detail, the foregoing description is in all aspects illustrative and not restrictive. It is understood that numerous unillustrated modifications can be devised.

Embodiments can freely be combined with each other, and can be modified or omitted as appropriate.

### EXPLANATION OF REFERENCE SIGNS

1 insulating substrate, 2 insulating layer, 3 metal pattern, 5 depression, 6 projection, 7 capture portion, 10 electrode, 11 receiving portion, 12 protrusion, 20 semiconductor element, 31 metal powder, 200 power converter, 201 main conversion circuit, 202 drive circuit, 203 control circuit, 400 moving vehicle.

1. A semiconductor device comprising:
an insulating substrate including an insulating layer and a metal pattern disposed on the insulating layer; and
an electrode bonded on the metal pattern, wherein
the electrode includes a receiving portion in a portion inward of a peripheral portion of a bonded surface being a surface of the electrode bonded on the metal pattern, the receiving portion being recessed upward and capable of receiving metal powder generated during bonding of the electrode and the metal pattern, and
the peripheral portion of the bonded surface of the electrode is bonded on the metal pattern.

2. The semiconductor device according to claim 1, wherein
the receiving portion is a recess formed in a central portion of the bonded surface of the electrode.

3. The semiconductor device according to claim 1, wherein
the receiving portion is a groove formed along the peripheral portion of the bonded surface of the electrode.

4. The semiconductor device according to claim 1, wherein
the metal pattern includes, in a portion opposing the bonded surface of the electrode, a depression recessed downward.

5. The semiconductor device according to claim 4, wherein
the metal pattern includes, in the depression thereof, a projection protruding upward and received in the receiving portion of the electrode.

6. The semiconductor device according to claim 1, wherein
the metal pattern includes a capture portion in a portion opposing the peripheral portion of the bonded surface of the electrode, the capture portion being made of a different material from the metal pattern and capable of capturing the metal powder.

7. The semiconductor device according to claim 1 further comprising
a semiconductor element bonded on the metal pattern, wherein
the semiconductor element comprises a wide bandgap semiconductor.

8. A power converter comprising:
a main conversion circuit to convert input power for output, the main conversion circuit including the semiconductor device according to claim 1;
a drive circuit to output, to the semiconductor device, a drive signal to drive the semiconductor device; and
a control circuit to output, to the drive circuit, a control signal to control the drive circuit.

9. A moving vehicle comprising the power converter according to claim 8 mounted thereon.

10. A semiconductor device manufacturing method of manufacturing the semiconductor device according to claim 1, the semiconductor device manufacturing method comprising:
(a) preparing the insulating substrate and the electrode; and
(b) bringing the peripheral portion of the bonded surface of the electrode into contact with the metal pattern, and ultrasonically bonding the peripheral portion of the bonded surface of the electrode on the metal pattern while applying a load using an ultrasonic bonding tool.

11. The semiconductor device manufacturing method according to claim 10, wherein
in step (a), the receiving portion is a groove formed along the peripheral portion of the bonded surface of the electrode, and the electrode includes, in a portion inward of the groove, a protrusion protruding downward.
